(19) United States
(12) Patent Application Publication
(10) Pub. No.: US 2014/0209021 A1
(43) Pub. Date: Jul. 31, 2014

(54) RAW MATERIAL GAS SUPPLY DEVICE, FILM FORMING APPARATUS, FLOW RATE MEASURING METHOD, AND NON-TRANSITORY STORAGE MEDIUM

(71) Applicant: TOKYO ELECTRON LIMITED, Tokyo (JP)

(72) Inventors: Mitsuya INOUE, Nirasaki City (JP); Makoto TAKADO, Oshu-shi (JP); Atsushi ANDO, Oshu-shi (JP)

(73) Assignee: TOKYO ELECTRON LIMITED, Tokyo (JP)

(21) Appl. No.: 14/167,613

(22) Filed: Jan. 29, 2014

(30) Foreign Application Priority Data
Jan. 29, 2013 (JP) 2013-014688

(51) Int. Cl. C23C 16/448; G01F 1/00

(52) U.S. Cl. CPC C23C 16/4481; G01F 1/00
USPC 118/712; 137/486; 73/195; 137/10

(57) ABSTRACT

Provided is a raw material gas supply device which includes: a raw material container; a carrier gas supply unit configured to supply a carrier gas into the container via a carrier gas flow path; a first flow rate measurement unit configured to measure a flow rate of the carrier gas flowing therethrough and output the same as a first flow rate measurement value; a raw material gas supply path configured to supply a raw material gas containing a vaporized raw material into a film forming apparatus; a second flow rate measurement unit configured to measure a flow rate of the raw material gas flowing therethrough and output the same as a second flow rate measurement value; and a flow rate calculation unit configured to calculate a difference between the first and second flow rate measurement values and to convert the difference into a vaporization flow rate of the raw material.

### CROSS-REFERENCE TO RELATED APPLICATION

This application claims the benefit of Japanese Patent Application No. 2013-014688, filed on Jan. 29, 2013, in the Japan Patent Office, the disclosure of which is incorporated herein in its entirety by reference.

### TECHNICAL FIELD

The present disclosure relates to a technique for measuring a flow rate of a raw material which is supplied to a film forming apparatus.

### BACKGROUND

To form a film on a substrate (hereinafter, referred to as “wafer”) such as a semiconductor wafer, various methods such as a CVD (Chemical Vapor Deposition) method, an ALD (Atomic Layer Deposition) method and the like are used. The CVD method includes supplying a raw material gas onto a surface of a wafer, and heating the wafer such that the raw material gas is subjected to a chemical reaction. The ALD method includes adsorbing an atomic layer or molecular layer formed of the raw material gas onto a surface of a wafer, supplying a reaction gas for oxidization and reduction of the raw material gas to produce reaction products, and repeatedly performing a sequence of these operations to deposit layers, which are formed of the reaction products, on the wafer. The above operations are performed by supplying the raw material gas into a reaction chamber which accommodates a plurality of wafers and is in a vacuum atmosphere.

Raw materials used in the CVD and ALD methods, when they are vaporized into raw material gas, often have a low vapor pressure. Such raw material gas is obtained by supplying a carrier gas into a raw material container that accommodates a liquid or solid raw material, followed by vaporizing the raw material into the carrier gas. To control a thickness or quality of a film formed on the wafer, it is required to measure an amount of the raw material contained in the raw material gas. There is known a thermal mass flow meter as an apparatus for measuring a flow rate of the raw material gas. However, such a thermal mass flow meter may not be suitable for measuring a concentration of the raw material contained in the raw material gas which has undergone concentration changes.

In the related art, a film forming process in manufacturing a semiconductor is performed by employing a method including: supplying a carrier gas into an evaporator where a liquid raw material is received; foaming (bubbling) the carrier gas to evaporate the liquid raw material; measuring a mass flow rate of an obtained mixed gas using a mass flow meter; and detecting a vaporization amount of the liquid raw material based on a difference between a mass flow rate of the carrier gas and the measured mass flow rate of the mixed gas. The mass flow rate of the carrier gas is controlled by a first mass flow controller. In a case where the vaporization amount of the liquid raw material contained in the mixed gas is varied, the technique controls an amount of a buffer gas to be supplied to the mixed gas and the supply amount of the carrier gas are controlled by a second mass flow controller, and a period of time during which the carrier gas passes through the liquid raw material. Thus, the mass flow rate of the mixed gas (containing the carrier gas, the buffer gas and the vaporized liquid raw material) and a component fraction thereof are constantly maintained.

In the conventional technique, the component fraction of the mixed gas depends on a position at which the buffer gas is supplied. For example, in a case where the buffer gas is introduced through a downstream side of the mass flow meter, the mass flow meter may fail to measure a correct flow rate. In addition, in the thermal mass flow meter, when a component of gas to be measured is varied, it is necessary to modify a conversion factor which is used in converting measurement results of the mass flow meter into an actual flow rate. As such, the thermal mass flow meter fails to measure the correct mass flow rate unless the conversion factor is modified responsive to a variation in component ratio of the mixed gas.

Unfortunately, the conventional technique does not teach modifying the conversion factor when the component of gas is varied. In addition, the use of meters other than the thermal mass flow meter fails to correctly measure the mass flow rate of the mixed gas whose component fraction is varied.

On the other hand, in a case where the buffer gas is introduced through an upstream side of the mass flow meter, if a total of the flow rates of the carrier gas and the buffer gas is constantly kept while keeping the vaporization amount of the liquid raw material received in the evaporator at a constant level, a mixing ratio of the mixed gas supplied to the mass flow meter converges to a constant value. This enables the mass flow rate of the mixed gas to be measured without modifying the conversion factor, even if the thermal mass flow meter is used. However, when the mixing ratio of the mixed gas is varied, the conventional technique fails to measure the mass flow rate of the mixed gas.

### SUMMARY

Some embodiments of the present disclosure provide a raw material gas supply device, a film forming apparatus, a flow rate measuring method and a non-transitory storage medium storing the same, which are capable of measuring a flow rate of a raw material even if a concentration of a raw material contained in a raw material gas is varied.

According to one embodiment of the present disclosure, provided is a raw material gas supply device for use in a film forming apparatus which forms a film on a substrate, which includes: a raw material container configured to accommodate a liquid or solid raw material; a carrier gas supply unit configured to supply a carrier gas into the raw material container via a carrier gas flow path; a first flow rate measurement unit configured to measure a flow rate of the carrier gas flowing through the carrier gas flow path and output the measured flow rate of the carrier gas as a first flow rate measurement value; a raw material gas supply path configured to supply a raw material gas containing a vaporized raw material inside the raw material container into the film forming apparatus; a second flow rate measurement unit configured to measure a flow rate of the raw material gas flowing through the raw material gas supply path, and output the measured flow rate of the raw material gas as a second flow rate measurement value; and a flow rate calculation unit configured to calculate a difference value between the first flow rate measurement value measured at the first flow rate measurement unit and the second flow rate measurement value measured at the second flow rate measurement unit, and configured to convert the difference value into a vaporization flow rate of the raw material.

According to another embodiment of the present disclosure, provided is a film forming apparatus, which includes the aforementioned raw material gas supply device and a film formation processing unit provided in a downstream side of the raw material gas supply device and configured to perform a film formation process on a substrate using a raw material gas supplied from the raw material gas supply device.

According to yet another embodiment of the present disclosure, provided is a method of measuring a vaporization flow rate of a raw material which is supplied to a film forming apparatus which forms a film on a substrate, the method including: supplying a carrier gas into a raw material container configured to accommodate a liquid or solid raw material via a carrier gas flow path; vaporizing the raw material; measuring a flow rate of the carrier gas flowing through the carrier gas flow path as a first flow rate measurement value; supplying a raw material gas containing the vaporized raw material inside the raw material container into the film forming apparatus via a raw material gas supply path; measuring, by a mass flow meter calibrated by the carrier gas, a flow rate of the raw material gas flowing through the raw material gas supply path as a second flow rate measurement value; calculating a difference value between the first flow rate measurement value and the second flow rate measurement value; and converting the difference value into the vaporization flow rate of the raw material.

According to still another embodiment of the present disclosure, provided is a non-transitory storage medium storing a program for controlling a raw material gas supply device for use in a film forming apparatus configured to form a film on a substrate, wherein the program causes the raw material gas supply device to perform the aforementioned method.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a schematic configuration of a film forming apparatus including a raw material gas supply device according to the present disclosure.

FIG. 2 is a view showing a configuration of a mass flow meter provided in the raw material gas supply device.

FIG. 3 is a view showing a configuration of a split-flow type mass flow meter including bypass paths as a reference example.

FIG. 4 is a graph showing a relationship between a vaporization flow rate of a raw material and a flow rate measurement value obtained by a mass flow meter.

FIG. 5 is a graph showing a relationship between a difference value between a flow rate measurement value and a flow rate of a carrier gas as a function of a vaporization flow rate.

FIG. 6 is a flowchart showing a sequence of operations for calculating a vaporization flow rate, which is performed in the raw material gas supply device.

FIG. 7 is a view showing a relationship between a vaporization flow rate and a flow rate measurement value.

FIG. 8 is a graph showing a relationship between a flow rate of a carrier gas and a correction coefficient of a flow rate measurement value.

FIG. 9 is a graph showing a case where a vaporization flow rate and a flow rate measurement value are not in a proportional relationship.

FIG. 10 is a graph showing a case where a vaporization flow rate and a flow rate measurement value are not in a proportional relationship.

FIG. 11 is a view showing a configuration of an experimental apparatus used in some embodiment.

FIG. 12 is a graph showing a relationship between a supply flow rate of an alternative gas and a flow rate measurement value according to a first experimental example.

FIG. 13 is a graph showing a relationship between a supply flow rate of an alternative gas and a difference between a flow rate measurement value and a flow rate of a carrier gas according to the first experimental example.

FIG. 14 is a graph showing a relationship between a supply flow rate of an alternative gas and a flow rate measurement value according to a second experimental example.

FIG. 15 is a graph showing a relationship between the supply flow rate of an alternative gas and a difference between a flow rate measurement value and a flow rate of a carrier gas according to the second experimental example.

### DETAILED DESCRIPTION

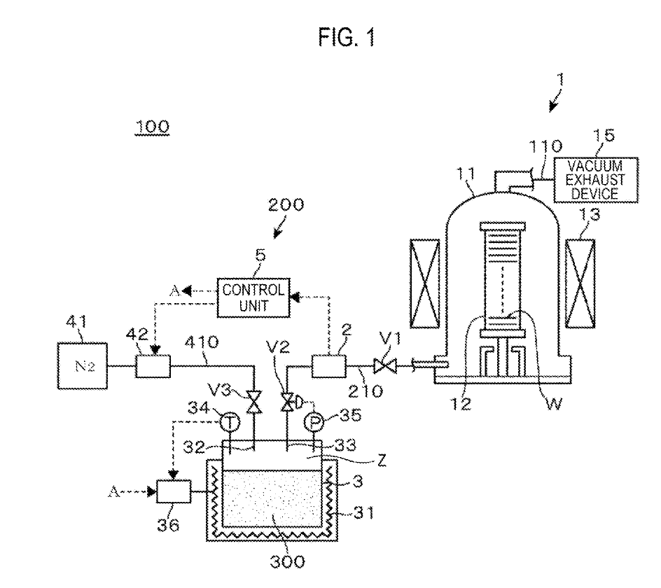

Hereinafter, an example of a configuration of a film forming apparatus including a raw material gas supply device of the present disclosure will be described with reference to FIG. 1. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A film forming apparatus 100 of the present disclosure includes a film formation processing device 1 configured to perform a film formation process on a substrate (e.g., wafer W) using a Chemical Vapor Deposition (CVD) method, and a raw material gas supply device 200 configured to supply a raw material gas into the film formation processing device 1.

The film formation processing device 1 corresponds to a main body of a batch type CVD equipment. In the film formation processing device 1, a wafer boat 12 with a plurality of wafers W loaded therein is transferred into a vertical reaction chamber 11 and subsequently, the reaction chamber 11 is evacuated by a vacuum exhaust unit 15 equipped with a vacuum pump or the like via an exhaust line 110. Thereafter, the raw material gas is supplied from the raw material gas supply device 200 into the reaction chamber 11 and subsequently, the wafers W are heated by a heating unit 13 installed outside the reaction chamber 11. That is, the film formation process is performed by employing the above operations.

As an example, a formation of a polyimide-based organic insulating film will be described. The polyimide-based organic insulating film is formed when two kinds of raw materials such as pyromellitic dianhydride (PMDA) and 4,4′-diaminodiphenyl ether (ODA: 4,4′-Oxydianiline) react to each other. The raw material gas supply device 200 of FIG. 1 is configured to heat and sublimate (vaporize) one (e.g., the PMDA) of the raw materials that is solid at normal temperature, and supply the same together with a carrier gas into the film formation processing device 1.

The raw material gas supply device 200 according to one embodiment includes a raw material container 3 configured to receive the raw material (the PMDA) therein, a carrier gas supply unit 41 configured to supply a carrier gas into the raw material container 3, and a raw material gas supply path 210 through which a raw material gas (containing a vaporized PMDA gas and the carrier gas) generated inside the raw material container 3 is flown into the film formation processing device 1.

The PMDA stored in the raw material container 3 is defined as a solid raw material 300. The raw material container 3 is surrounded with a jacket-shaped heating unit 31 incorporating a resistance heating element therein. A temperature detection unit (T) 34 is configured to detect temperature of a gas phase zone Z inside the raw material container 3 and provide the detected temperature to a power supply unit 36 as indicated by a dashed line. The power supply unit 36 increases or decreases an amount of power supplied to the raw material container 3 based on the detected temperature provided from the temperature detection unit (T) 34 and a control signal A supplied from a control unit 5 (which will be described later). In this way, an internal temperature of the raw material container 3 is controlled. The heating unit 31 is configured to heat the solid raw material 300 to a predetermined set temperature at which the solid raw material 300 can be vaporized and does not undergo a thermal decomposition. An example of the predetermined set temperature may include 250 degrees C.

A carrier gas nozzle 32 and a discharge nozzle 33 are connected to the gas phase zone Z defined above the solid raw material 300 in the raw material container 3. The carrier gas nozzle 32 is configured to introduce the carrier gas supplied from the carrier gas supply unit 41 into the raw material container 3 therethrough. The discharge nozzle 33 is configured to discharge the raw material gas generated inside the raw material container 3 to the raw material gas supply path 210 therethrough. The carrier gas nozzle 32 and the discharge nozzle 33 are opened in the gas phase zone Z.

The carrier gas nozzle 32 is coupled to a carrier gas flow path 410 in which a mass flow controller (MFC) 42 is installed. The carrier gas supply unit 41 is disposed at an upstream side of the carrier gas flow path 410. An example of the carrier gas may include an inert gas such as a nitrogen (N₂) gas and a helium (He) gas. In this embodiment, the N₂ gas is used as the carrier gas.

The MFC 42 includes, for example, a thermal mass flow meter (MFM), and a flow rate control unit which is configured to control a flow rate of the carrier gas flowing through the carrier gas flow path 410 to a predetermined level based on a flow rate measurement value of the carrier gas measured at the MFM. The MFM of the MFC 42 corresponds to a first flow rate measurement unit of this embodiment, and a flow rate of the carrier gas measured at the MFM corresponds to a first flow rate measurement value Q1 (hereinafter, sometimes referred to as a “flow rate Q1” simply).

The discharge nozzle 33 is coupled to the raw material gas supply path 210 in which an on/off valve V1, a pressure control valve V2 and a mass flow meter (MFM) 2 are installed. The raw material gas discharged from the raw material container 3 is supplied into the film formation processing device 1 via the raw material gas supply path 210. The interior of the raw material container 3 is evacuated by the vacuum exhaust unit 15 through the reaction chamber 11 and the raw material gas supply path 210, to maintain the interior of the raw material container 3 at a depressurized atmosphere. An opening degree of the pressure control valve V2 is controlled based on a pressure value measured at a pressure detection unit (P) 35 so that an internal pressure of the raw material container 3 is controlled.

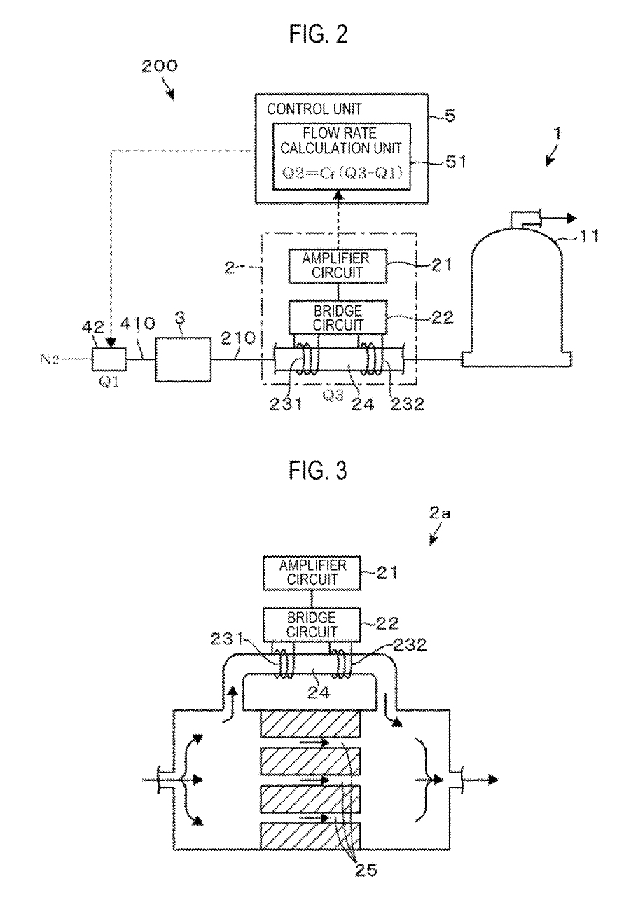

As shown in FIG. 2, the MFM 2 is arranged in the raw material gas supply path 210. The MFM 2 is configured as a thermal mass flow meter which includes a narrow tube part 24, resistive elements 231 and 232, a bridge circuit 22 and an amplifier circuit 21. The narrow tube part 24 through which the total amount of the raw material gas discharged from the raw material container 3 is flown, is arranged in the raw material gas supply path 210. Each of the resistive elements 231 and 232 is wound around a tube wall of the narrow tube part 24 at upstream and downstream sides. The bridge circuit 22 and the amplifier circuit 21 are configured to detect a change in temperature of the tube wall of the narrow tube part 24 as a change in resistance of the respective resistive elements 231 and 232, and convert the change into a flow rate signal corresponding to a mass flow rate of the raw material gas. The change in temperature of the tube wall is caused by the raw material gas flowing through the narrow tube part 24.

The MFM 2 is calibrated by the carrier gas (the N₂ gas). When the carrier gas containing no the raw material (i.e., the PMDA) is flown through the MFM 2, the MFM 2 outputs a flow rate signal corresponding to the flow rate of the carrier gas. The flow rate signal varies in a range of, e.g., 0 to 5 [V]. Such a flow rate signal corresponds to a respective gas flow rate [sccm] over the full range including zero (under a standard temperature and pressure: zero degree C. and 1 atm). Based on such a correspondence relationship, a value obtained by converting the flow rate signal into the flow rate of the raw material gas is defined as a flow rate measurement value. The flow rate measurement value may be calculated by a flow rate calculation unit 51 (which will be described later) or the MFM 2.

When the raw material gas (consisting of the vaporized PMDA gas and the carrier gas) is flown through the MFM 2, a flow rate of the raw material gas is measured at the MFM 2. The MFM 2 corresponds to a second flow rate measurement unit of this embodiment. The flow rate of the raw material gas measured at the MFM 2 is defined as a second flow rate measurement value Q3 (hereinafter, sometimes referred to as a “flow rate Q3” simply).

FIG. 3 shows a configuration of a split-flow type MFM 2a as a reference example. As shown in FIG. 3, in the MFM 2a, a portion of a raw material gas supplied thereto is flown through bypass paths 25, and the other gas is flown through the narrow tube part 24 with the resistive elements 231 and 232 wound therearound so that the flow rate Q3 is measured. Occasionally, the raw material gas supplied from the raw material container 3 may be varied in concentration over time. Such a variation in concentration may cause a fluctuation in viscosity of the raw material gas which is supplied to the MFM 2a. Moreover, this results in a variation in proportion (or split-flow ratio) at which the raw material gas is flown through the narrow tube part 24 and the bypass paths 25, which makes it difficult to correctly measure the flow rate Q3.

According to the thermal MFM 2 in which the total amount of the raw material gas supplied thereto is flown through only the narrow tube part 24 as shown in FIG. 2, it is possible to correctly measure the flow rate Q3 of the raw material gas without being affected by the fluctuation in viscosity thereof.

In this embodiment, the thermal MFM 2 has been described to be employed in the present disclosure, but is not limited thereto. In some embodiments, the split-flow type MFM 2a as shown in FIG. 3 may be employed as long as the viscosity of the raw material gas is substantially constantly maintained even if the concentration of the raw material gas is varied.

In the film forming apparatus 100 (including the film formation processing device 1 and the raw material gas supply device 200) configured as above, the raw material gas supply device 200 is connected to the control unit 5. The control unit 5 is configured with, e.g., a computer including a central processing unit (CPU) and a storage unit, which are not shown in drawings. The storage unit may store a program which includes steps (commands) allowing the control unit 5 to control a sequence of operations of the film forming apparatus 100. Specifically, the sequence of operations includes: loading the wafer boat 12 into the reaction chamber 11; evacuating the reaction chamber 11; supplying the raw material gas from the raw material gas supply device 200 for film formation; terminating the supply of the raw material gas; and unloading the wafer boat 12 from the reaction chamber 11. The program is stored in a storage medium, for example, a hard disk, a compact disk, a magneto-optical disk, and a memory card or the like, and is installed in the computer.

Although in the above, the MFM 2 has been described to be calibrated by the carrier gas, the MFM 2 occasionally fails to correctly measure the flow rate Q3 of the raw material gas containing both the vaporized PMDA gas and the carrier gas flowing through the raw material gas supply path 210. Meanwhile, by flowing only the carrier gas (without the vaporized PMDA gas) through the MFM 2, it is possible to obtain a correct flow rate. Further, by arranging the MFC 42 at the upstream side of the raw material container 3 in the raw material gas supply device 200, the carrier gas is controlled to flow at the flow rate Q1 corresponding to a predetermined set value.

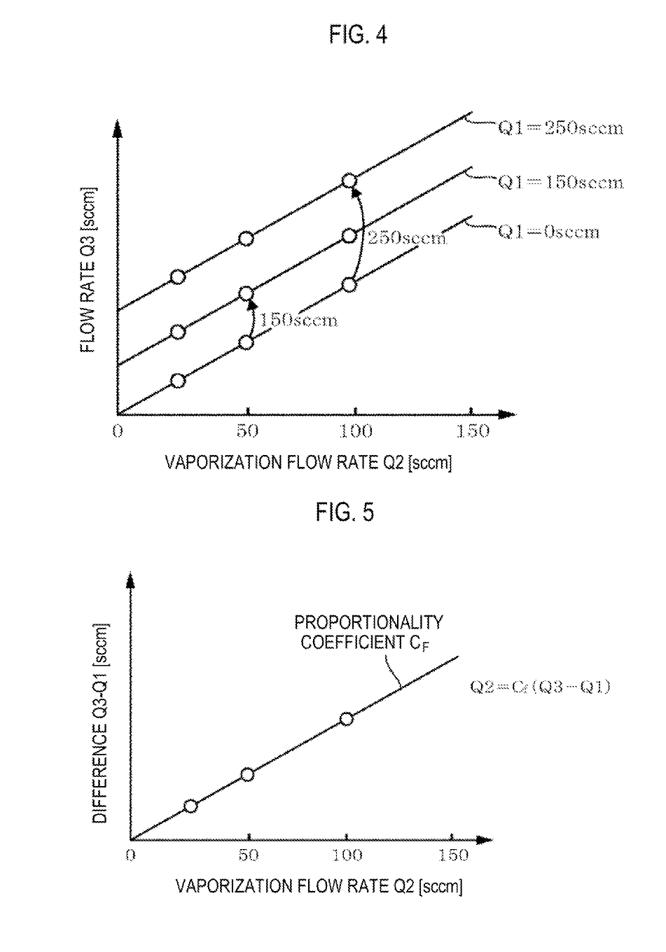

As shown in FIG. 2, the control unit 5 includes the flow rate calculation unit 51 which is configured to calculate a vaporization flow rate measurement value Q2 (hereinafter, sometimes referred to as a “vaporization flow rate Q2” simply) of the raw material contained in the raw material gas based on the flow rate Q3 of the raw material gas that is measured at the MFM 2, and the flow rate Q1 (the predetermined set value) of the carrier gas. Hereinafter, a method of calculating the vaporization flow rate Q2 of the raw material will be described with reference to FIGS. 4 and 5.

FIG. 4 is a graph showing a variation in the flow rate Q3 of the raw material gas that is measured at the MFM 2 as a function of the flow rate Q1 of the carrier gas and the vaporization flow rate Q2 of the raw material with Q2 [sccm] as a horizontal axis and Q3 [sccm] as a vertical axis. In FIG. 4, the flow rate Q1 of the carrier gas is used as a parameter.

As shown in FIG. 4, when the flow rate Q1 of the carrier gas is, e.g., 0 [sccm], the vaporization flow rate Q2 of the raw material (i.e., the PMDA) bears a proportionate relationship to the flow rate Q3 obtained by flowing the raw material gas through the MFM 2. In the circumstance, when the carrier gas is supplied at the flow rate Q1 of 150 [sccm] and is mixed with the vaporized PMDA gas, the MFM 2 adds the flow rate Q1 of 150 [sccm] to the flow rate Q1 of 0 [sccm] and outputs the added flow rate as the flow rate Q3. Similarly, when the carrier gas is supplied at the flow rate Q1 of 250 [sccm] and is mixed with the vaporized PMDA gas, the MFM 2 adds the flow rate Q1 of 250 [sccm]) to the flow rate Q1 of 0 [sccm] and outputs the added flow rate as the flow rate Q3.

Assuming that the aforementioned proportionate relationship is established, a difference value (Q3−Q1) between the flow rate Q3 and the flow rate Q1 (i.e., the predetermined set value) represents a value obtained when the flow rate Q1 is 0 [sccm] as shown in FIG. 4. In view of the foregoing, a proportionality coefficient C_{f} between the vaporization flow rate Q2 of the raw material and the flow rate Q3 of the raw material gas is previously determined Thus, by multiplying the difference value by the proportionality coefficient C_{f}, the vaporization flow rate Q2 of the raw material can be obtained by the following equation:

Q2 =C_{f}(Q3−Q1) Eq. (1)

The flow rate calculation unit 51 calculates the vaporization flow rate Q2 of the raw material using the above equation Eq. (1) based on the program stored in the storage unit of the control unit 5. According to this calculation, even if the concentration of the raw material contained in the raw material gas is varied, which makes it difficult to determine a conversion factor which is used in obtaining the correct flow rate of the raw material gas, the flow rate calculation unit 51 can calculate the vaporization flow rate Q2 of the raw material.

As will be described in experimental examples hereinafter, it was found that the vaporization flow rate Q2 of the raw material contained in the raw material gas can be measured using the MFM 2 calibrated by the carrier gas and the above equation Eq. (1) (in the experimental examples, a hydrogen (H₂) gas and a sulfur hexafluoride (SF₆) gas were used as the raw material gas).

For example, the proportionality coefficient C_{f} can be determined by the following method. The raw material gas is generated by calculating a weighing capacity of the raw material container 3 which receives the solid raw material 300 used as the raw material therein, followed by changing a heating temperature of the heating unit 31, followed by supplying the carrier gas into the raw material container 3 at the flow rate Q1. The vaporization flow rate Q2 is determined based on a change in weight of the solid raw material 300, and the flow rate Q3 is obtained by flowing the raw material gas through the MFM 2. As shown in FIG. 4, the flow rate Q3 are determined as a function of the flow rate Q1 of the carrier gas and the vaporization flow rate Q2 so that the relationship between the vaporization flow rate Q2 and the flow rate Q3 is obtained. If is checked that the relationship in which the flow rate Q1 of the carrier gas is added to the flow rate Q3 (that is obtained when the flow rate of the carrier gas is 0 [sccm]) is established, the difference value (Q3−Q1) is calculated. As shown in FIG. 5, the proportionality coefficient C_{f} is determined by dividing the vaporization flow rate Q2 by the difference value.

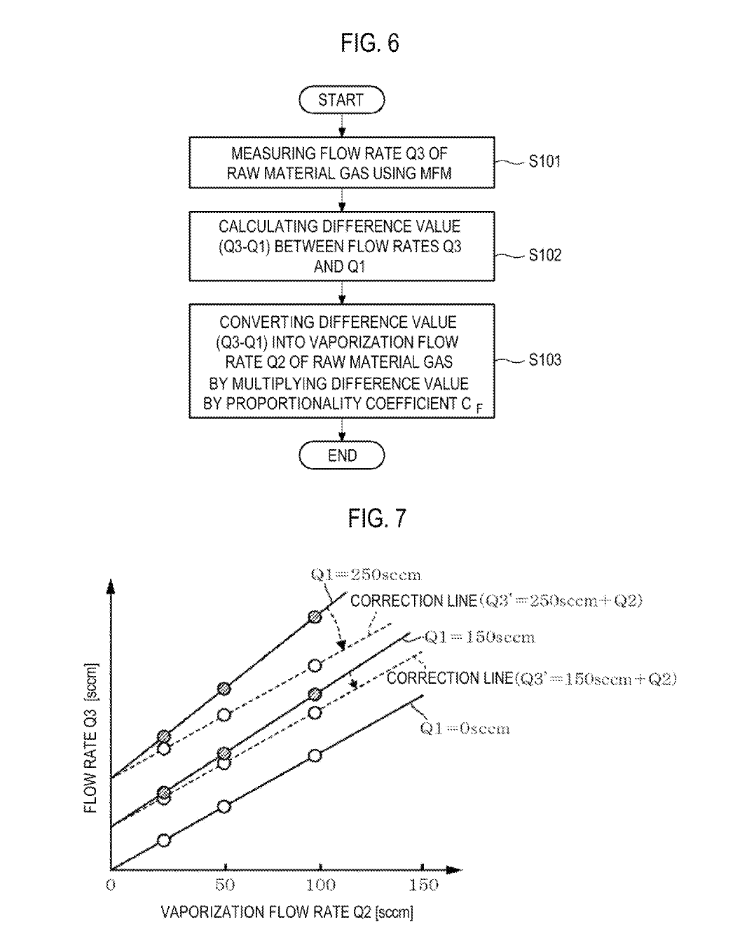

Next, an operation of the film forming apparatus 100 according to another embodiment will be described with reference to FIGS. 1 and 6.

First, the wafer boat 12 is loaded into the reaction chamber 11 and the interior of the reaction chamber 11 is subsequently evacuated. Thereafter, an on/off valve V3 is opened, and the carrier gas is supplied from the carrier gas supply unit 41 into the raw material container 3 while being adjusted at the flow rate Q1 corresponding to the predetermined set value. In this process, the raw material gas is generated. Subsequently, the raw material gas is supplied into the film formation processing device 1 where the wafers W are heated by the heating unit 13. On a surface of the heated wafer W, the vaporized PMDA gas contained in the raw material gas reacts with the ODA gas that is supplied through a raw material gas supply line (not shown). Thus, the polyimide-based organic insulating film is formed on the surface of the wafer W.

The operation of calculating the vaporization flow rate Q2 of the raw material will be described. First, the pressure control valve V2 is opened, and the raw material gas is introduced through the discharge nozzle 33 and the pressure control valve V2 into the narrow tube part 24 of the MFM 2 such that the flow rate Q3 of the raw material gas is measured (step S101 in FIG. 6). The flow rate calculation unit 51 calculates the difference value (Q3−Q1) between the flow rate Q3 and the flow rate Q1 (the predetermined set value) of the carrier gas.

The MFC 42 is configured to control the flow rate Q1 of the carrier gas based on a flow rate measurement value of the carrier gas that is measured using the incorporated MFM. It should be noted that therefore, when the flow rate Q3 of the raw material gas is stable, the flow rate of the carrier gas falls within an allowable range of error. In this embodiment, the predetermined set value of the MFC 42 was used as the flow rate Q1 of the carrier gas. Alternatively, the flow rate calculation unit 51 may calculate the difference value (Q3−Q1) based on the flow rate measurement value provided from the MFM of the MFC 42.

Thereafter, the flow rate calculation unit 51 calculates the vaporization flow rate Q2 of the raw material by multiplying the difference value (Q3−Q1) by the proportionality coefficient C_{f} (step S103). In formation of the organic insulating film having a desired thickness and quality, the vaporization flow rate Q2 of the raw material (the PMDA) that is obtained in the above manner, may be utilized as information for adjusting the flow rate Q1 of the carrier gas, an internal pressure of the raw material container 3 or the like. Further, the vaporization flow rate Q2 may also be utilized as monitor information for continuously monitoring a vaporization flow rate of the raw material.

After a predetermined period of time, the carrier gas supply unit 41 stops supplying the carrier gas. Simultaneously, the on/off valve V1 is closed and the supply of the raw material gas containing the raw material (the PMDA) into the film formation processing device 1 is terminated. In addition, after stopping the supply of the raw material gas containing the ODA into the film formation processing device 1, the interior of the reaction chamber 11 is kept at the atmospheric pressure. Thereafter, the wafer boat 12 is unloaded from the reaction chamber 11 and the sequence of film forming processes is completed.

In the raw material gas supply device 200 according to this embodiment, the following effects are manifested. The flow rate of the raw material gas containing the vaporized PMDA gas and the carrier gas is measured at the thermal MFM 2 which is calibrated by the carrier gas. Then, the flow rate Q1 of the carrier gas is subtracted from the flow rate Q3. The difference value obtained based on the subtraction is converted into the vaporization flow rate Q2 of the raw material (the PMDA). In this way, it is possible to measure the vaporization flow rate Q2 of the raw material even if a concentration of the raw material contained in the raw material gas is varied.

In the example shown in FIG. 4, the value obtained by adding the flow rate Q1 of the carrier gas to the vaporization flow rate Q2 of the raw material measured at the MFM 2 has been described to be defined as the flow rate Q3 of the raw material gas.

FIG. 7 is a graph showing a case where the flow rate Q3 of the raw material gas increases as the flow rate Q1 of the carrier gas increases. In this case, the raw material gas is generated while changing (i.e., increasing or decreasing) the flow rate Q1 of the carrier gas. The difference value as described above is calculated by detecting a deviation of the flow rate Q3 from the sum of the flow rates Q1 and Q2, and compensating the deviation.

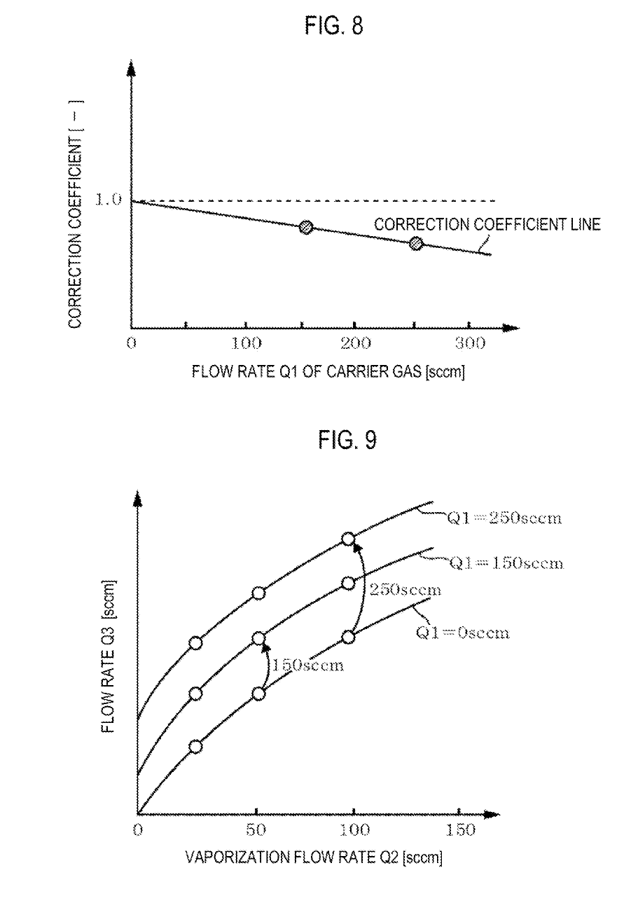

Specifically, as shown in FIG. 7, a correction flow rate Q3′(=Q1+Q2) is calculated by multiplying the flow rate Q3 of the raw material gas by a correction coefficient for offsetting the deviation. Thereafter, a difference value (Q3′−Q1) is calculated, and the vaporization flow rate Q2 of the raw material is determined by multiplying the difference value by the proportionality coefficient C_{f}. FIG. 8 is a graph showing an example of a relationship between the flow rate Q1 of the carrier gas and the correction coefficient, which is obtained as the experiment result.

The calculation of the correction flow rate Q3′ is not limited to the above experiment, but may be calculated by other method. As an example, in a case where a line of the flow rate Q3 as a function of the vaporization flow rate Q2 of the raw material is parallel to a line of the correction flow rate Q3′, the correction flow rate Q3′ may be calculated by adding or subtracting the correction coefficient to and from the flow rate Q3. In addition, a correction equation Q3′=Q3(Q1, Q2) which indicates a relationship between the flow rate Q3 and the correction flow rate Q3′ as a function of the flow rate Q1 of the carrier gas and the vaporization flow rate Q2 of the raw material, may be defined by, e.g., a least square method. By such a correction equation, the correction process may be performed.

It is appreciated that, when the proportionality coefficient C_{f} for converting the difference value (Q3−Q1) into the vaporization flow rate Q2 of the raw material is varied depending on the flow rate Q1 of the carrier gas, the calculation of the correction equation Q3′=Q3(Q1, Q2) is performed so as to offset the variation.

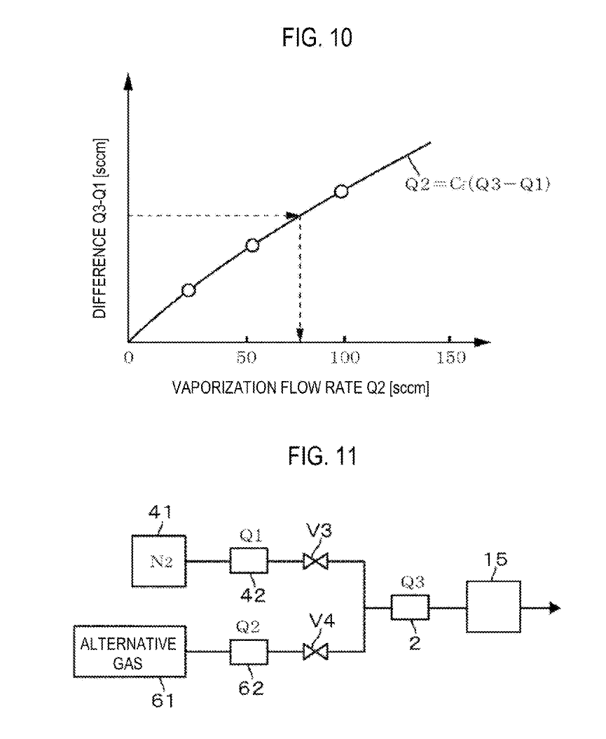

FIGS. 9 and 10 are graphs showing cases where the vaporization flow rate Q2 of the raw material and the flow rate Q3 measured at the MFM 2 are not in a proportional relationship, respectively. In these cases, an approximation equation Q2=C_{f}(Q3−Q1) indicating a relationship between the vaporization flow rate Q2 and the difference value (Q3−Q1) is defined by, e.g., a least square method. By substituting the difference value (Q3−Q1) into the approximation equation, the vaporization flow rate Q2 is obtained.

In some embodiments, the MFM 2 used in measuring the flow rate Q3 of the raw material gas may be calibrated using a calibration gas different from the carrier gas (the N₂ gas in this embodiment). Further, the MFM 2 is able to measure a flow rate of gas different from the calibration gas using the conversion factor. Therefore, the vaporization flow rate Q2 can be determined by converting a flow rate Q3″ that is obtained by flowing the raw material gas through the MFM 2 calibrated by the calibration gas (e.g., a helium (He) gas), into the flow rate Q3 corresponding to the N₂ gas, followed by substituting the same into the above equation Eq. (1).

Accordingly, “the thermal mass flow meter that is calibrated by the carrier gas” described in this embodiment, may include the MFC 42 calibrated by the calibration gas different from the carrier gas. In this case, a flow rate that is measured at the MFC 42 is converted into the flow rate Q1 corresponding to the carrier gas using the conversion factor. Thus, the second flow rate measurement value (i.e., the flow rate Q3) is obtained.

While in the above embodiments, the PMDA, which is used as a raw material of the polyimide-based organic insulating film and is solid at the normal temperature, has been described to be supplied using the raw material gas supply device 200 of the present disclosure, the present disclosure is not limited thereto. In some embodiments, the ODA, which is another raw material of the polyimide-based organic insulating film and is solid at the normal temperature, may be supplied. Specifically, by the aforementioned method, it is possible to calculate the flow rate of the raw material gas that is obtained by heating the ODA until it is liquefied, introducing the carrier gas into the liquid ODA, and bubbling the liquid ODA into the carrier gas. Furthermore, the present disclosure may be applied in measuring a flow rate of a raw material, which is used in forming a thin film containing various metals such as aluminum, hafnium, and zirconium, including trimethyl aluminum (TMA), triethyl aluminum (TEA), tetradimethylamino hafnium (TDMAH), tetrakisethylmethylamino hafnium (TEMAH), tetrakisethylmethylamino zirconium (TEMAZ) or the like.

### Experiment

In this experiment, a carrier gas of a predetermined flow rate and an alternative gas of a raw material were mixed. Subsequently, a mixed gas obtained thus was flown through the MFM 2 so that the flow rate Q3 of the mixed gas was obtained. Thereafter, a variation in the flow rate Q3 of the raw material gas and the difference value (Q3−Q1) as a function of the flow rate Q2 of the alternative gas were examined.

### Experimental Conditions

As shown in FIG. 11, the carrier gas (N₂ gas) was supplied from the carrier gas supply unit 41 through the on/off valve V3 while being adjusted at the flow rate Q1 by the MFC 42. In addition, the alternative gas was supplied from an alternative gas supply unit 61 through an on/off valve V4 while being adjusted as the flow rate Q2 by a MFC 62. The carrier gas and the alternative gas were mixed with each other inside the raw material container 3 as described above. Thereafter, the mixed gas was flown through the MFM 2 where the flow rate Q3 was obtained. A downstream side of the MFM 2 was arranged to be evacuated by the vacuum exhaust unit 15 up to a pressure of about 2000 Pa.

### First Experimental Example

A hydrogen (H₂) gas (having a viscosity of 1.3×10⁻⁵ [Pa·s] and a molecular weight of 2), which has a viscosity similar to the PMDA gas (having a viscosity of 1.4×10⁻⁵ [Pa·s] and a molecular weight of 218), was used as the alternative gas. The supply flow rate Q1 of the carrier gas (the N₂ gas) was varied in the order of 0, 100, 250, and 500 [sccm]. In this case, the supply flow rate Q2 of the alternative gas (the H₂ gas) was varied in a range of 0 to 1000 [sccm].

### Second Experimental Example

A sulfur hexafluoride (SF₆) gas (having a viscosity of 2.5×10⁻⁵ [Pa·s] and a molecular weight of 146) having a molecular weight similar to PMDA, was used as the alternative gas. The supply flow rate Q1 of the carrier gas (the N₂ gas) was varied in the order of 0, 100, 250, and 500 [sccm]. In this case, the supply flow rate Q2 of the alternative gas (the SF₆ gas) was varied in a range of 0 to 600 [sccm].

### Experimental Results

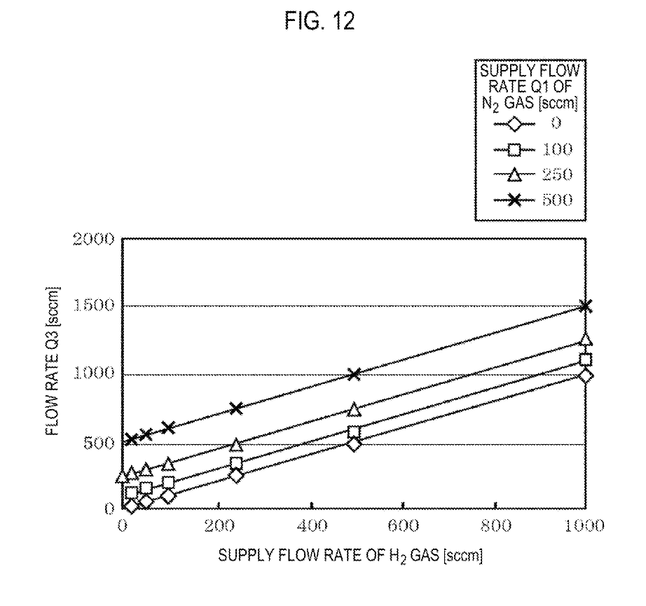

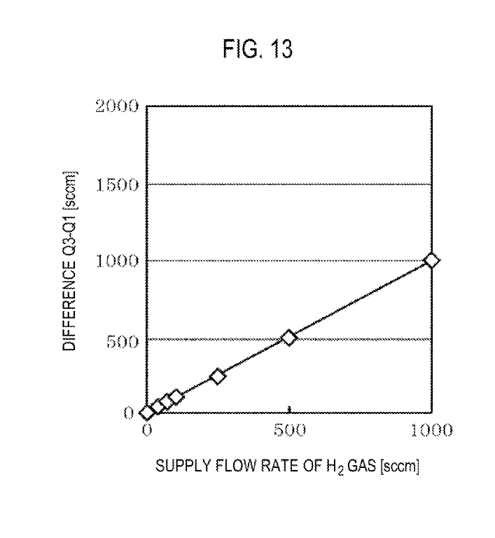

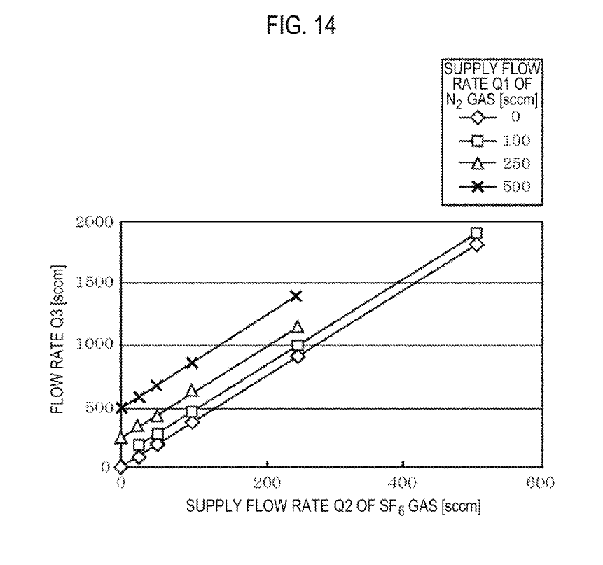

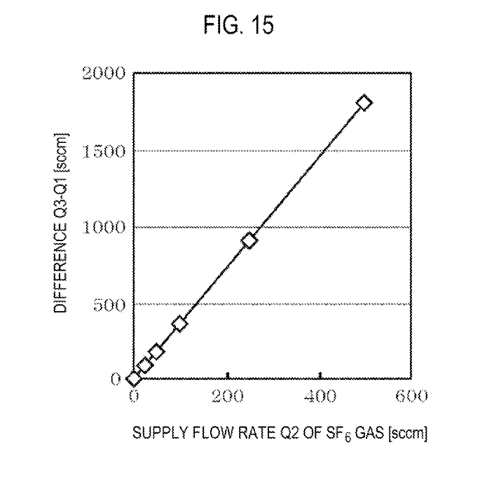

FIGS. 12 and 13 are graphs showing the results of the first experimental example, and FIGS. 14 and 15 are graphs showing the results of the second experimental example. In FIGS. 12 and 14, each of horizontal axes represents the supply flow rate Q2 of the alternative gases (the H2 gas and the SF6 gas), and each of vertical axes represents the flow rate Q3 measured as the MFM 2. Also, in FIGS. 13 and 15, each of horizontal axes represents the supply flow rate Q2 of the alternative gas (the H2 gas and the SF6 gas), and each of vertical axes represents the difference value (Q3−Q1) between the flow rate Q3 and the flow rate Q1. Indeed, since the difference values (Q3−Q1) corresponding to points at which the supply amounts of the alternative gas are equal to one another, are superimposed with each other so as to be difficult to identify when plotted in the respective graphs, the difference values corresponding to respective supply amounts are indicated by one plot, for the sake of simplicity in FIGS. 13 and 15.

As shown in FIGS. 12 and 14, the first and second experimental examples have shown that, when the supply flow rate Q1 of the carrier gas is 0 [sccm], the supply flow rate Q2 of the alternative gas (both the H₂ gas and the SF₆ gas) and the flow rate Q3 are in a proportional relationship (see a symbol “⋄” indicated in FIGS. 12 and 14). Further, the first and second experimental examples have shown that, when the supply flow rate Q1 of the carrier gas is varied in the order of 100, 250, and 500 [sccm] (see symbols “□”, “Δ”, “ X ” indicated in FIGS. 12 and 14), a line of the flow rate Q3 is arranged to be approximately parallel to that of the flow rate Q3 obtained when only the alternative gas is supplied (i.e., when the supply flow rate Q1 of the carrier gas is 0 [sccm]).

Furthermore, as will be appreciated from FIGS. 13 and 15 in which the difference values (Q3−Q1) are plotted with respect to the supply flow rate Q2 of the alternative gas, the supply flow rate Q2 and the difference value (Q3−Q1) are in a proportional relationship. An approximate straight-line of the difference value (Q3−Q1) to the supply flow rate Q2 was obtained using a least square method based on all the measurement results. The experimental examples have shown that a deviation of an estimation supply flow rate (which is obtained by substituting the difference value (Q3−Q1) into the approximate straight-line) and the actual supply flow rate Q2 falls within a range of ±2% for both the alternative gases. Therefore, it was found that the flow rate Q2 of the alternative gas can be measured using the above method described with reference to FIGS. 4 and 5 and the above equation Eq. (1).

According to the present disclosure in some embodiments, using a thermal flow meter that is calibrated by a carrier gas, a flow rate of a raw material gas containing a vaporized raw material gas and the carrier gas is measured, followed by obtaining a difference value between the measured flow rate and a predetermined flow rate of the carrier gas, and followed by converting the difference value into a flow rate of a raw material. Thus, it is possible to measure the flow rate of the raw material even if a concentration of the raw material contained in the raw material gas is varied.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A raw material gas supply device for use in a film forming apparatus which forms a film on a substrate, comprising:
a raw material container configured to accommodate a liquid or solid raw material;
a carrier gas supply unit configured to supply a carrier gas into the raw material container via a carrier gas flow path;
a first flow rate measurement unit configured to measure a flow rate of the carrier gas flowing through the carrier gas flow path and output the measured flow rate of the carrier gas as a first flow rate measurement value;
a raw material gas supply path configured to supply a raw material gas containing a vaporized raw material inside the raw material container into the film forming apparatus;
a second flow rate measurement unit configured to measure a flow rate of the raw material gas flowing through the raw material gas supply path, and output the measured flow rate of the raw material gas as a second flow rate measurement value; and
a flow rate calculation unit configured to calculate a difference value between the first flow rate measurement value measured at the first flow rate measurement unit and the second flow rate measurement value measured at the second flow rate measurement unit, and configured to convert the difference value into a vaporization flow rate of the raw material.

2. The device of claim 1, wherein the first flow rate measurement unit includes a flow rate control unit configured to control a flow rate of the carrier gas to a predetermined set value.

3. The device of claim 1, wherein the flow rate calculation unit is further configured to convert the difference value into the vaporization flow rate of the raw material using a proportionality coefficient.

4. The device of claim 3, wherein when the proportionality coefficient is varied depending on the flow rate of the carrier gas supplied from the carrier gas supply unit, the flow rate calculation unit is further configured to calculate the difference value by compensating the second flow rate measurement value measured at the second flow rate measurement unit to meet the variation in the proportionality coefficient.

5. The device of claim 1, wherein the flow rate calculation unit is configured to convert the difference value into the vaporization flow rate of the raw material based on an approximation equation that represents a relationship between the difference value and the flow rate of the raw material.

6. The device of claim 1, wherein the second flow rate measurement unit includes a mass flow meter which is calibrated by the carrier gas.

7. The device of claim 6, wherein the mass flow meter includes a narrow tube part in which the total amount of the raw material gas is flown, and resistive elements wound around the narrow tube part, and
wherein the mass flow meter is configured to measure the second flow rate measurement value based on a change in resistance of the resistive elements.

8. A film forming apparatus, comprising:
a raw material gas supply device of claim 1; and
a film formation processing unit provided in a downstream side of the raw material gas supply device and configured to perform a film formation process on a substrate using a raw material gas supplied from the raw material gas supply device.

9. A method of measuring a vaporization flow rate of a raw material which is supplied to a film forming apparatus which forms a film on a substrate, the method comprising:
supplying a carrier gas into a raw material container configured to accommodate a liquid or solid raw material via a carrier gas flow path;
vaporizing the raw material;
measuring a flow rate of the carrier gas flowing through the carrier gas flow path as a first flow rate measurement value;
supplying a raw material gas containing the vaporized raw material inside the raw material container into the film forming apparatus via a raw material gas supply path;
measuring, by a mass flow meter calibrated by the carrier gas, a flow rate of the raw material gas flowing through the raw material gas supply path as a second flow rate measurement value;
calculating a difference value between the first flow rate measurement value and the second flow rate measurement value; and
converting the difference value into the vaporization flow rate of the raw material.

10. The method of claim 9, wherein measuring a first flow rate measurement value includes controlling the flow rate of the carrier gas supplied into the raw material container to a predetermined set value.

11. The method of claim 9, wherein converting a difference value includes multiplying the difference value by a proportionality coefficient.

12. The method of claim 11, wherein when the proportionality coefficient is varied depending on the flow rate of the carrier gas supplied from the carrier gas supply unit, converting a difference value includes compensating the second flow rate measurement value to meet the variation in the proportionality coefficient.

13. The method of claim 9, wherein converting a difference is performed based on an approximation equation that represents a relationship between the difference value and the flow rate of the raw material.

14. A non-transitory storage medium storing a program for controlling a raw material gas supply device for use in a film forming apparatus configured to form a film on a substrate,
wherein the program causes the raw material gas supply device to perform the method of claim 9.
